(19) United States
(12) Patent Application Publication
(10) Pub. No.: US 2022/0204830 A1
(43) Pub. Date: Jun. 30, 2022

(54) BORON NITRIDE POWDER, METHOD FOR PRODUCING SAME, COMPOSITE MATERIAL, AND HEAT DISSIPATION MEMBER

(71) Applicant: Denka Company Limited, Chuo-ku, Tokyo (JP)

(72) Inventors: Go TAKEDA, Chuo-ku, Tokyo (JP); Takaaki TANAKA, Chuo-ku, Tokyo (JP)

(73) Assignee: Denka Company Limited, Chuo-ku, Tokyo (JP)

(21) Appl. No.: 17/441,740

(22) PCT Filed: Mar. 25, 2020
(86) PCT No.: PCT/JP2020/013479

§ 371 Date: Sep. 22, 2021

(30) Foreign Application Priority Data
Mar. 28, 2019 (JP) 2019-062911

(51) Int. Cl. C09K 5/14; C01B 21/064; C08K 3/38

(52) U.S. Cl. CPC C09K 5/14; C01B 21/0645; C08K 3/38; C01P 2004/50; C01P 2004/61; C01P 2006/32; C01P 2004/03; C08K 2003/385; C08K 2201/005; C08K 2201/016; C01P 2004/54

(57) ABSTRACT

Provided is a boron nitride powder including: an agglomerated particle obtained by aggregating flaky primary particles, in which in-plane directions of the primary particles are oriented in a direction parallel to a short-side direction of the agglomerated particle. In addition, provided is a method for producing a boron nitride powder including: a nitriding step of firing a boron carbide powder having an aspect ratio of 1.5 to 10 in a nitrogen pressurized atmosphere to obtain a fired product; and a crystallization step of heating a formulation that contains the fired product and a boron source to produce flaky boron nitride primary particles and obtaining a boron nitride powder containing an agglomerated particle obtained by aggregating the primary particles.

### TECHNICAL FIELD

The present disclosure relates to a boron nitride powder, a method for producing the same, a composite material, and a heat dissipation member.

### BACKGROUND ART

Boron nitride has lubricity, high thermal conductivity, insulation properties, and the like, and is widely used in applications such as a solid lubricant, a conductive filler, and an insulation filler. In recent years, due to the increase in performance of electronic devices or the like, it is required for boron nitride to have excellent thermal conductivity.

The thermal characteristics of flaky boron nitride usually have anisotropy. That is, it is known that the thermal conductivity in a thickness direction (c-axis direction) is extremely lower than that in an in-plane direction (a-b in-plane direction) perpendicular to the thickness direction. For example, the thermal conductivity in an a-axis direction is 400 W/(m·K), while the thermal conductivity in the c-axis direction is 2 W/(m·K). For this reason, the thermal characteristics of a composite material obtained, for example, from a resin by filling with a boron nitride powder is greatly affected by an alignment state of boron nitride particles in the composite. For example, if a composite material molded into a sheet shape through pressing is produced, in many cases, boron nitride particles are oriented in a direction perpendicular to the pressing direction, and the thermal conductivity in the pressing direction is lowered. In order to avoid such a phenomenon, an attempt to make fine boron nitride particles have a spherical shape having an average circularity of greater than or equal to 0.80 has been made in Patent Literature 1.

In addition, it has been proposed in Patent Literature 2 that the peak intensity ratio [I(002)/I(100)] of a boron nitride powder be reduced to reduce anisotropy in thermal conductivity.

### CITATION LIST

### Patent Literature

[Patent Literature 1] PCT International Publication No. WO2015/122379
[Patent Literature 2] Japanese Unexamined Patent Publication No. 2014-40341

### SUMMARY OF INVENTION

### Technical Problem

FIGS. 9 and 10 are scanning electron micrographs respectively showing surfaces and cross sections of agglomerated particles in the related art. As shown in FIGS. 9 and 10, in a case where primary particles contained in agglomerated particles are not oriented, the anisotropy of thermal conductivity can be reduced. Whereas, a heat dissipation member having superior heat dissipation characteristics as compared to the related art, and a boron nitride powder and a composite material which are suitably used therefor are required in accordance with highly integrated circuits in electronic components.

Thus, the present disclosure provides a boron nitride powder having a sufficiently high thermal conductivity, a method for producing the same, and a composite material. In addition, the present disclosure provides a heat dissipation member having sufficiently excellent heat dissipation characteristics.

### Solution to Problem

A boron nitride powder according to an aspect of the present disclosure includes: an agglomerated particle obtained by aggregating flaky primary particles, in which in-plane directions of the primary particles are oriented in a direction parallel to a short-side direction of the agglomerated particle. This can sufficiently increase thermal conductivity in a short-side direction of the agglomerated particle. Accordingly, for example, when a composite material containing a boron nitride powder and a resin is obtained through uniaxial pressing, the thermal conductivity in the uniaxial pressing direction can be sufficiently increased. Such a composite material is very useful as a heat dissipation member. In the expression “in-plane directions being oriented in a direction parallel to a short-side direction of the agglomerated particle” in the present disclosure, it is unnecessary for in-plane directions of all the primary particles to be parallel to a short-side direction. For example, in-plane directions of some or all of the primary particles may not be completely parallel to a short-side direction. That is, even if the in-plane directions may deviate from the parallel direction, this is sufficient as long as some or all of the primary particles are arranged in directions closer to the parallel direction than in a case of non-orientation.

A boron nitride powder according to another aspect of the present disclosure includes: an agglomerated particle obtained by aggregating flaky primary particles, in which an orientation index [I(002)/I(100)] is less than or equal to 6.5. This boron nitride powder contains an agglomerated particle obtained by aggregating flaky primary particles having a sufficiently high thermal conductivity in the in-plane directions perpendicular to thickness directions. Since the orientation index [I(002)/I(100)] is less than or equal to 6.5, the orientation of the primary particles can be improved. Accordingly, when the boron nitride powder is used in a composite material, a heat dissipation member, or the like, the thermal conductivity can be sufficiently increased.

The above-described orientation index may be greater than or equal to 2.0 and less than 6.0. Accordingly, the thermal conductivity can be further increased.

An average particle diameter of the above-described boron nitride powder may be 15 to 200 μm. Accordingly, the thermal conductivity can be further increased.

An aspect ratio of the above-described boron nitride powder may be 1.3 to 9.0. Accordingly, when the boron nitride powder is used in a composite material or a heat dissipation member, the thermal conductivity can be sufficiently increased.

A method for producing a boron nitride powder according to an aspect of the present disclosure includes: a nitriding step of firing a boron carbide powder having an aspect ratio of 1.5 to 10 in a nitrogen pressurized atmosphere to obtain a fired product; and a crystallization step of heating a formulation that contains the fired product and a boron source to produce flaky boron nitride primary particles and obtaining a boron nitride powder containing an agglomerated particle obtained by aggregating the primary particles.

Since the boron carbide powder having an aspect ratio of 1.5 to 10 is used in this production method, agglomerated particles having a shape derived from the shape of the boron carbide powder can be obtained. Although the reason for this is unclear, flaky boron nitride primary particles grow in a direction different from an orientation direction of boron carbide particles, which is derived from a specific growth environment of boron nitride particles in which one boron carbide particle becomes one agglomerated boron nitride particle (aggregate). That is, boron nitride primary particles grow along a direction orthogonal to a longitudinal direction of boron carbide particles, and as a result, produce agglomerated particles which are aggregates with a significantly specific structure. This can enhance the orientation of the primary particles from the viewpoint of thermal conductivity. When the boron nitride powder containing agglomerated particles obtained by aggregating such primary particles is used in a composite material, a heat dissipation member, or the like, the thermal conductivity can be sufficiently increased.

In the above-described crystallization step, in-plane directions of the primary particles may be oriented in a direction parallel to a short-side direction of the agglomerated particle. Due to this, a boron nitride powder having a higher thermal conductivity can be obtained. In the above-described crystallization step, a boron nitride powder having an orientation index [I(002)/I(100)] of less than or equal to 6.5 may be obtained. Due to this, the boron nitride powder having a higher thermal conductivity can be obtained

A composite material according to an aspect of the present disclosure includes: a boron nitride powder containing an agglomerated particle obtained by aggregating flaky primary particles; and a resin, in which an orientation index [I(002)/I(100)] is less than or equal to 6.0. Such a composite material can have an enhanced orientation for the primary particles. Accordingly, the composite material has a sufficiently high thermal conductivity.

The composite material may include: any of the above-described boron nitride powders; and a resin. Such a composite material has a sufficiently high thermal conductivity since it contains the above-described boron nitride powder.

A heat dissipation member according to an aspect of the present disclosure includes: the above-described composite material. For this reason, thermal dissipation can be sufficiently increased.

### Advantageous Effects of Invention

According to the present disclosure, it is possible to provide a boron nitride powder having a sufficiently high thermal conductivity, a method for producing the same, and a composite material. In addition, the present disclosure can provide a heat dissipation member having sufficiently excellent heat dissipation characteristics.

### BRIEF DESCRIPTION OF DRAWINGS

FIG. 1 is a cross-sectional view schematically showing a cross section of an agglomerated particle contained in a boron nitride powder according to one embodiment.

FIG. 2 is a scanning electron micrograph (magnification: 500 times) showing an example of a cross section of an agglomerated particle.

FIG. 3 is a scanning electron micrograph (magnification: 1,000 times) showing an example of a boron nitride powder and an agglomerated particle contained therein.

FIG. 4 is a perspective view schematically showing an example of a flaky primary particle contained in an agglomerated particle.

FIG. 5 is a scanning electron micrograph (magnification: 2,000 times) showing an enlarged cross section of an agglomerated particle different from that in FIG. 2.

FIG. 6 is a view schematically showing a composite material according to one embodiment.

FIG. 7 is a scanning electron micrograph (magnification: 10,000 times) of a boron carbide powder of Example 1.

FIG. 8 is a scanning electron micrograph (magnification: 1,000 times) of a fired product of Example 1.

FIG. 9 is a scanning electron micrograph showing surfaces of agglomerated particles in the related art.

FIG. 10 is a scanning electron micrograph showing cross sections of agglomerated particles in the related art.

### DESCRIPTION OF EMBODIMENTS

Hereinafter, embodiments of the present disclosure will be described with reference to the drawings according to circumstances. However, the following embodiments are merely examples for describing the present disclosure and are not intended to limit the present disclosure to the following contents. In the description, the same reference numerals are given to the same elements or elements having the same function, and description thereof will not be repeated according to circumstances. In addition, unless otherwise specified, positional relationships such as above, below, left of, and right of are based on the positional relationships illustrated in the drawing. Furthermore, the dimensional ratios of elements are not limited to the ratios shown in the drawings.

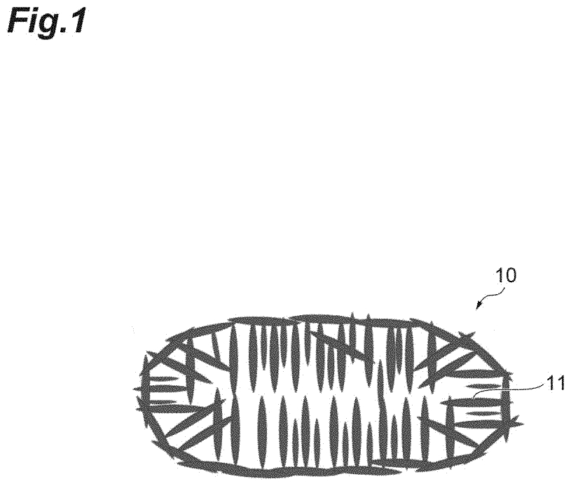

A boron nitride powder according to one embodiment includes anisotropic agglomerated particles obtained by aggregating flaky primary particles. FIG. 1 is a schematic diagram of an agglomerated particle contained in the boron nitride powder of the present embodiment. As shown in FIG. 1, an agglomerated particle 10 is not isotropic but is anisotropic, and is obtained by aggregating flaky primary particles 11 (boron nitride particles).

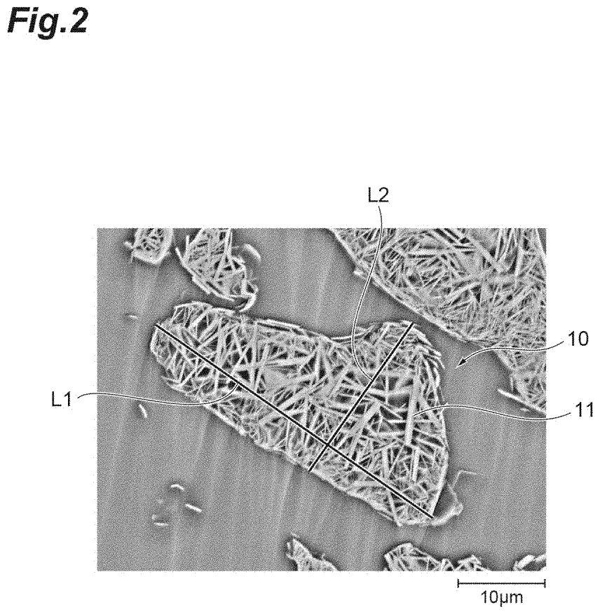

FIG. 2 is a scanning electron micrograph showing an example of a cross section of an agglomerated particle 10 contained in the boron nitride powder. As shown in FIG. 2, a long side L1 and a short side L2 which are orthogonal to each other can be drawn on the agglomerated particle 10. The long side L1 and the short side L2 are drawn according to the following procedure. In the image of the agglomerated particle 10, two points on the outer edge of the agglomerated particle 10 with the largest spacing are selected. A line segment connecting these two points is the long side L1. In addition, another two points on the outer edge of the agglomerated particle 10 with the largest spacing in a direction orthogonal to this long side L1 are selected. A line segment connecting these two points is the short side L2.

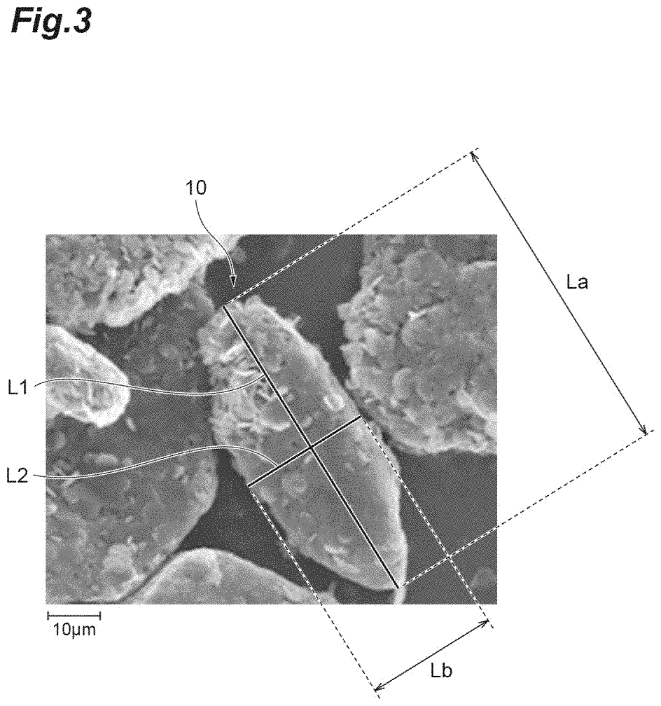

FIG. 3 is an image of a scanning electron microscope showing a surface of the agglomerated particle 10 contained in the boron nitride powder. A length La of the long side L1 and a length Lb of the short side L2 of the agglomerated particle 10 are measured on the surface image of the agglomerated particle 10 as shown in FIG. 3. La and Lb have a relationship of La>Lb. The measurement of La and Lb may be performed by incorporating the observation image as shown in FIG. 3 into image analysis software (for example, “Mac-view” manufactured by MOUNTECH Co., Ltd.)

Arbitrary 100 agglomerated particles 10 can be selected in a scanning electron microscope image as shown in FIG. 3 and La/Lb values of the respective agglomerated particles 10 can be calculated to obtain an aspect ratio of the boron nitride powder as an arithmetic average value of the La/Lb values. The aspect ratio of the boron nitride powder may be 1.3 to 9.0 from the viewpoint of further increasing the thermal conductivity of the boron nitride powder. In the present disclosure, a direction parallel to the long side L1 is referred to as a longitudinal direction, and a direction parallel to the short side L2 is referred to as a short-side direction.

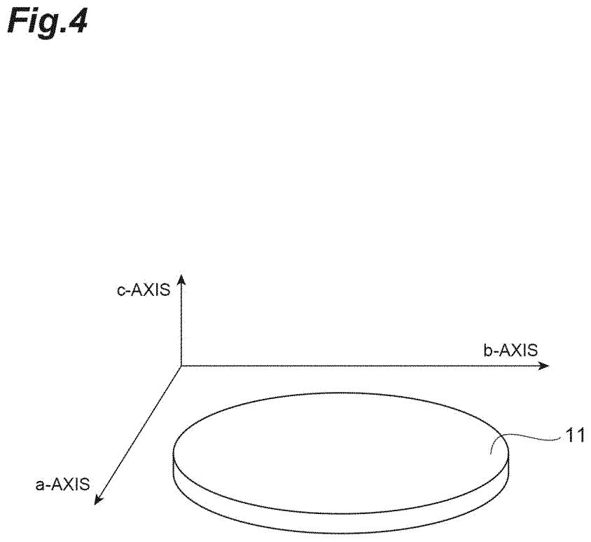

FIG. 4 is a perspective view schematically showing an example of a flaky primary particle 11 contained in an agglomerated particle 10. In the present disclosure, the c-axis direction is defined as a thickness direction of the primary particle 11, and the length along the c-axis direction is defined as a length of the primary particle 11. In addition, the direction parallel to an a-b plane orthogonal to the c-axis direction is defined as in-plane directions of the primary particle 11.

As shown in FIGS. 1 and 2, the primary particles 11 are oriented so that the in-plane directions of the primary particles follow the short-side direction of the agglomerated particle 10. In other words, the primary particles 11 are oriented so that the thickness directions of the primary particles follow the long-side direction of the agglomerated particle 10. Due to such orientation, the thermal conductivity in the short-side direction of the agglomerated particle 10 can be sufficiently increased.

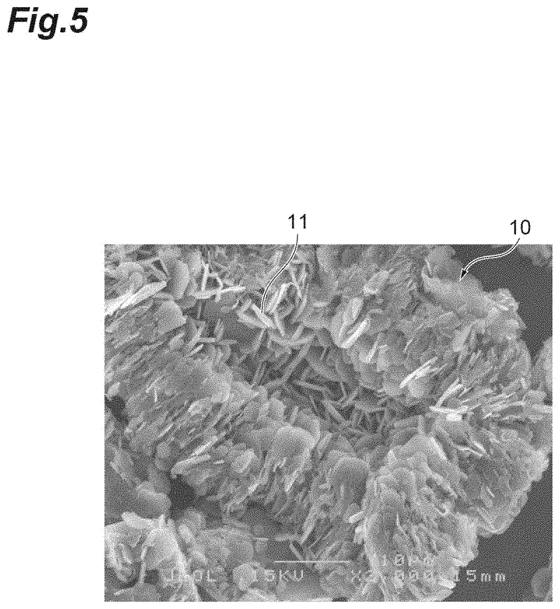

FIG. 5 is a scanning electron micrograph (magnification: 2,000 times) showing a cross section of an agglomerated particle different from that in FIG. 2. Also in this photograph, it can be seen that the in-plane directions of the primary particles 11 are oriented in a direction parallel to the short-side direction of the agglomerated particle 10.

In a case where the primary particles 11 are not oriented, that is, in a case where these are completely random and non-oriented, the orientation index [I(002)/I(100)] is about 6.7 (crystal density value [Dx] of “JCPDS [Powder X-Ray Diffraction Database]” No. 34-0421 [BN]) as disclosed in Patent Literature 2. In general, the orientation index of hexagonal boron nitride with high crystallinity is greater than 20.

On the other hand, the orientation index [I(002)/I(100)] of the boron nitride powder of the present embodiment is preferably less than or equal to 6.5. This orientation index may be less than 6.0 or less than 5.8. In this manner, the smaller the orientation index, the higher the proportion of the primary particles 11 of which the in-plane directions are oriented in the direction parallel to the short-side direction of the agglomerated particle 10. That is, when the in-plane directions of the primary particles 11 are oriented in the direction parallel to the short-side direction of the agglomerated particle 10, the orientation index is smaller than that in a case where the in-plane directions thereof are not oriented in such a direction.

If a molding raw material containing a boron nitride powder containing such an agglomerated particle 10 is uniaxially pressed, the uniaxial pressing direction and the in-plane directions of the flaky primary particles 11 are likely to be parallel to each other, and the thermal conductivity in a predetermined direction (uniaxial pressing direction) can be sufficiently increased. The orientation index of the boron nitride powder from the viewpoint of ease of production may be greater than or equal to 2.0, greater than or equal to 3.0, or greater than or equal to 4.0. The orientation index [I(002)/I(100)] can be obtained as a peak intensity ratio of the plane (002) to the plane (100) of X-ray diffraction.

The average particle diameter of the boron nitride powder of the present embodiment may be greater than or equal to 15 μm, greater than or equal to 20 μm, greater than or equal to 25 μm, or greater than or equal to 30 μm from the viewpoint of efficiently increasing the thermal conductivity. The average particle diameter may be less than or equal to 200 μm, less than or equal to 150 μm, less than or equal to 100 μm, less than or equal to 90 μm, or less than or equal to 80 μm so that the boron nitride powder is suitably used in a sheet-shaped composite material or the like.

The average particle diameter of the boron nitride powder in the present disclosure can be measured with a commercially available particle size distribution measuring device (for example, LS-13 320 manufactured by Beckman Coulter Inc.) for a laser diffraction scattering method.

An aspect ratio of the boron nitride powder may be 1.3 to 9.0. In a case where a molded body is obtained by uniaxially pressing a composite material containing such a boron nitride powder and a resin, agglomerated particles contained in the boron nitride powder tend to be oriented so that the short-side direction thereof and the pressing direction are parallel to each other. As a result, primary particles are oriented so that the in-plane directions thereof are parallel to the short-side direction, and the thermal conductivity of the composite material (composite sheet) or a heat dissipation member in the uniaxial pressing direction can be sufficiently increased.

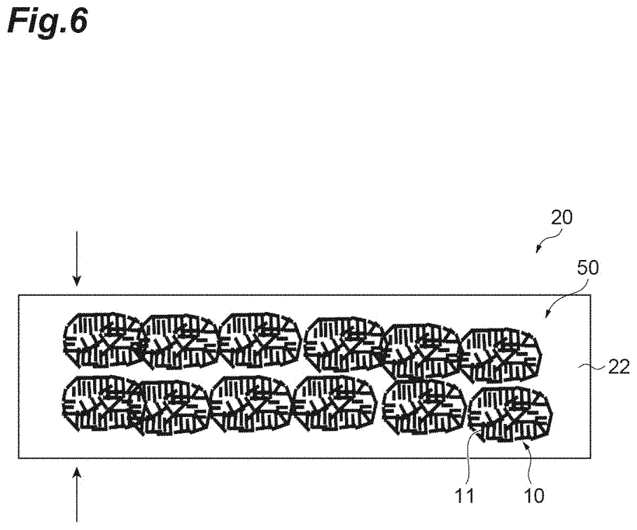

FIG. 6 is a view schematically showing a composite material according to one embodiment. FIG. 6 is a perspective view of the agglomerated particles 10 contained in a composite material 20 when the composite material 20 is viewed from the side surface. The composite material 20 contains a resin 22 and a boron nitride powder 50 dispersed in the resin 22 and is molded by being uniaxially pressed in the arrow direction shown in FIG. 6. The resin 22 may be cured or uncured. The composite material 20 may have a sheet shape.

Since the agglomerated particles 10 contained in the boron nitride powder 50 are anisotropic, the short-side direction thereof is substantially parallel to the uniaxial pressing direction indicated by the arrows in FIG. 6. For this reason, the in-plane directions of the primary particles 11 constituting the agglomerated particles 10 are likely to be parallel to the pressing direction. Accordingly, the composite material 20 particularly has excellent thermal conductivity in the uniaxial pressing direction. The agglomerated particles 10 being anisotropic in the present disclosure mean that these have a shape such that the orientation thereof changes according to the pressing direction in this manner. Specifically, the agglomerated particles may have a flat shape.

The composite material 20 containing the resin 22 and the boron nitride powder 50 may be a thermoconductive resin composition or may have a sheet shape such as a heat dissipation sheet. Examples of the resin 22 include an epoxy resin, a silicone resin, a silicone rubber, an acrylic resin, a phenolic resin, a melamine resin, a urea resin, an unsaturated polyester, a fluorine resin, a polyamide (for example, polyimide, polyamideimide, and polyetherimide), a polyester (for example, polybutylene terephthalate and polyethylene terephthalate), a polyphenylene ether, polyphenylene sulfide, a fully aromatic polyester, a polysulfone, a liquid crystal polymer, a polyethersulfone, a polycarbonate, a maleimide-modified resin, an ABS resin, an acrylonitrile-acrylic rubber-styrene (AAS) resin, and an acrylonitrile-ethylene-propylene-diene rubber-styrene (AES) resin. The resin 22 may be a mixture of resin raw materials thereof and a curing agent.

Of the above-described resins, an epoxy resin (for example, naphthalene-type epoxy resin) is particularly suitable as an insulating layer of a printed wiring board since it has excellent heat resistance and adhesive strength to a copper foil circuit. In addition, a silicone resin is suitable as a thermal interface material since it has excellent heat resistance, flexibility, and adhesiveness to a heat sink or the like.

The composite material 20 may be obtained by formulating the boron nitride powder 50, a raw material (monomer) becoming the above-described resin, and a curing agent at a predetermined ratio and curing the resin material with heat or light. Examples of curing agents in a case where an epoxy resin is used include a phenol novolac resin, an acid anhydride resin, an amino resin, and imidazoles. Among these, imidazoles are preferable. The formulation amount of this curing agent with respect to the raw material (monomer) may be 0.5 parts by mass to 15 parts by mass, or 1.0 parts by mass to 10 parts by mass.

The content of a boron nitride powder of the composite material 20 may be 30 to 85 volume % or 40 to 80 volume %. By setting the above-described content to be greater than or equal to 30 volume %, the thermal conductivity is sufficiently increased, and therefore, the composite material 20 having sufficient thermal conductivity can be obtained. By setting the above-described content to be less than or equal to 85 volume %, a number of voids generated during molding are reduced, and hence, the insulation properties and the mechanical strength can be further increased. The composite material 20 may contain components other than the boron nitride powder and the resin. The total content of the boron nitride powder and the resin in the composite material 20 may be greater than or equal to 80 mass %, greater than or equal to 90 mass %, or greater than or equal to 95 mass %.

Since the composite material 20 has excellent thermal conductivity, it can be suitably used as, for example, a heat dissipation member such as a heat dissipation sheet and a metal base substrate. The composite material 20 contains the agglomerated particle 10 obtained by aggregating the flaky primary particles 11. The in-plane directions of the primary particles 11 in the agglomerated particle 10 are oriented in the direction parallel to the short-side direction of the agglomerated particle 10. Accordingly, the orientation index [I(002)/I(100)] of the composite material 20 is less than or equal to 6.0, and the composite material 20 has excellent thermal conductivity. The orientation index [I(002)/I(100)] of the composite material 20 may be less than 5.5, or may be less than or equal to 5.0 from the viewpoint of further improving the thermal conductivity. The orientation index [I(002)/I(100)] can be obtained as a peak intensity ratio of the plane (002) to the plane (100) of X-ray diffraction similarly to the boron nitride powder.

A method for producing a boron nitride powder according to one embodiment includes: a nitriding step of firing a boron carbide powder in a nitrogen pressurized atmosphere to obtain a fired product; and a crystallization step of heating a formulation that contains the fired product and a boron source to produce flaky boron nitride primary particles and obtaining a boron nitride powder containing an agglomerated particle obtained by aggregating the primary particles. Due to this production method, the boron nitride powder having the above-described characteristics can be obtained.

A boron carbide powder having an aspect ratio of 1.5 to 10 is used. This aspect ratio may be greater than or equal to 1.7, or may be greater than or equal to 1.8 from the viewpoint of increasing the thermal conductivity of the composite material in the thickness direction. On the other hand, the above-described aspect ratio may be less than or equal to 9 or may be less than or equal to 8 from the viewpoint of lowering the anisotropy of the thermal conductivity. This aspect ratio can be obtained through the same method as the above-described method of obtaining the aspect ratio of the boron nitride powder.

The boron carbide powder can be prepared, for example, according to the following procedure. After mixing boric acid with acetylene black, the mixture is heated at 1,800° C. to 2,400° C. for 1 to 10 hours in an inert gas atmosphere to obtain a boron carbide mass. After this boron carbide mass is pulverized, it can be sieved, and washing, removal of impurities, drying, and the like can be appropriately performed to prepare a boron carbide powder. Here, the boron carbide powder having the above-described aspect ratio can be obtained, for example, by performing pulverization under relatively mild conditions and then performing a combination of classification using a vibration sieve and airflow classification. Specifically, the boron carbide powder may be obtained by removing particles having a size greater than or equal to a predetermined size using a vibration sieve and removing particles having a size less than or equal to a predetermined size through airflow classification. The coarse particles generated at this time may be reused through pulverization and classification again to obtain a boron carbide powder having the above-described aspect ratio.

In the nitriding step, a boron carbide powder is fired in a nitrogen pressurized atmosphere to obtain a fired product containing boron carbonitride (B₄CN₄). The firing temperature in the nitriding step may be higher than or equal to 1,800° C. or may be higher than or equal to 1,900° C. In addition, the firing temperature may be lower than or equal to 2,400° C. or may be lower than or equal to 2,200° C. The firing temperature may be, for example, 1,800° C. to 2,400° C.

The pressure in the nitriding step may be higher than or equal to 0.6 MPa or may be higher than or equal to 0.7 MPa. In addition, the pressure may be lower than or equal to 1.0 MPa, or may be lower than or equal to 0.9 MPa. The pressure may be, for example, 0.6 MPa to 1.0 MPa. If the pressure is too low, there is a tendency for nitriding of boron carbide to be unlikely to proceed. Whereas, if the pressure is too high, there is a tendency for production costs to increase.

The concentration of nitrogen gas in a nitrogen pressurized atmosphere in the nitriding step may be greater than or equal to 95 volume %, or may be greater than or equal to 99.9 volume %. The firing time in the nitriding step is not particularly limited as long as nitriding sufficiently proceeds, and may be, for example, 6 to 30 hours or may be 8 to 20 hours.

In the crystallization step, a formulation that contains a boron source and the fired product containing boron carbonitride obtained in the nitriding step is heated to produce flaky boron nitride primary particles, and a boron nitride powder containing an agglomerated particle obtained by aggregating the primary particles is obtained. That is, in the crystallization step, a boron carbonitride is decarbonized and flaky primary particles having a predetermined size are produced, and these are aggregated to obtain the boron nitride powder containing the agglomerated particles.

Examples of boron sources include boric acid, boron oxide, or a mixture thereof. The formulation heated in the crystallization step may contain well-known additives.

The formulation ratio of boron carbonitride with respect to the boron source in the formulation can be appropriately set according to the molar ratio. In a case where boric acid or boron oxide is used as the boron source, 100 to 300 parts by mass of boric acid or boron oxide may be formulated with 100 parts by mass of boron carbonitride, or 150 to 250 parts by mass of boric acid or boron oxide may be formulated with 100 parts by mass of boron carbonitride, for example.

The heating temperature for heating the formulation in the crystallization step may be, for example, higher than or equal to 1,800° C. or higher than or equal to 2,000° C. The heating temperature may be, for example, lower than or equal to 2,200° C. or lower than or equal to 2,100° C. If the heating temperature is too low, there is a tendency for grain growth to insufficiently proceed. In the crystallization step, heating may be performed in a normal pressure (atmospheric pressure) atmosphere or may be performed at a pressure exceeding the atmospheric pressure through pressurization. In a case of pressurization, the pressure may be, for example, lower than or equal to 0.5 MPa or lower than or equal to 0.3 MPa.

The heating time in the crystallization step may be longer than or equal to 0.5 hours, or may be longer than or equal to 1 hour, longer than or equal to 3 hours, longer than or equal to 5 hours, or longer than or equal to 10 hours. The heating time may be shorter than or equal to 40 hours, shorter than or equal to 30 hours, or shorter than or equal to 20 hours. The heating time may be, for example, 0.5 to 40 hours or 1 to 30 hours. If the heating time is too short, there is a tendency for grain growth to insufficiently proceed. Whereas, if the heating time is too long, there is a tendency for the step to be industrially disadvantageous.

A boron nitride powder can be obtained through the above-described steps. A pulverization step may be performed after the crystallization step. In the pulverization step, a usual pulverizer or disintegrator can be used. For example, a ball mill, a vibration mill, a jet mill, or the like can be used. In the present disclosure, “disintegration” is also included in “pulverization”. A boron nitride powder having an average particle diameter of 15 to 200 μm may be prepared through pulverization and classification.

In the above-described production method, a boron carbide powder having a predetermined aspect ratio is used. The shapes of agglomerated particles contained in the obtained boron nitride powder are derived from the shape of a boron carbide powder. Accordingly, the agglomerated particles contained in the boron nitride powder obtained through the above-described production method are anisotropic. These agglomerated particles are obtained by aggregating flaky primary particles. Since the primary particles are highly orientated, the boron nitride powder containing the agglomerated particle has excellent thermal conductivity. In-plane directions of the boron nitride primary particles may be oriented in a direction parallel to a short-side direction of the agglomerated particle. The boron nitride powder may have the above-described orientation index.

Some embodiments have been described above, but the present disclosure is not limited to any of the above-described embodiments.

### EXAMPLES

The contents of the present invention will be described in more detail with reference to examples and comparative examples, but the present disclosure is not limited to the following examples.

<Preparation of Boron Carbide Powder>

### Example 1

100 Parts by mass of orthoboric acid manufactured by Nippon Denko Co., Ltd. and 35 parts by mass of acetylene black (trade name: HS100) manufactured by Denka Company Limited were mixed with each other using a henschel mixer. A graphite crucible was filled with the obtained mixture which was then heated at 2,200° C. for 5 hours in an arc furnace in an argon atmosphere to obtain agglomerated boron carbide (B₄C). The obtained agglomerate was coarsely pulverized with a jaw crusher to obtain a coarse powder. The coarse powder was further pulverized with a ball mill having silicon carbide balls ($10 mm) to obtain a pulverized powder. The pulverization with a ball mill was performed at a rotation frequency of 20 rpm for 60 minutes. Thereafter, the pulverized powder was classified with a vibration sieve having an opening of 45 μm. Fine powder on the sieve was subjected to airflow classification with a Classiel classifier to obtain a boron carbide powder having a particle diameter of greater than or equal to 10 μm. In this manner, the boron carbide powder obtained had an aspect ratio of 2.5 and an average particle diameter of 30 μm (measurement methods thereof will be described below). The carbon content of the obtained boron carbide powder was 19.9 mass %. The carbon content was measured with a carbon/sulfur simultaneous analyzer.

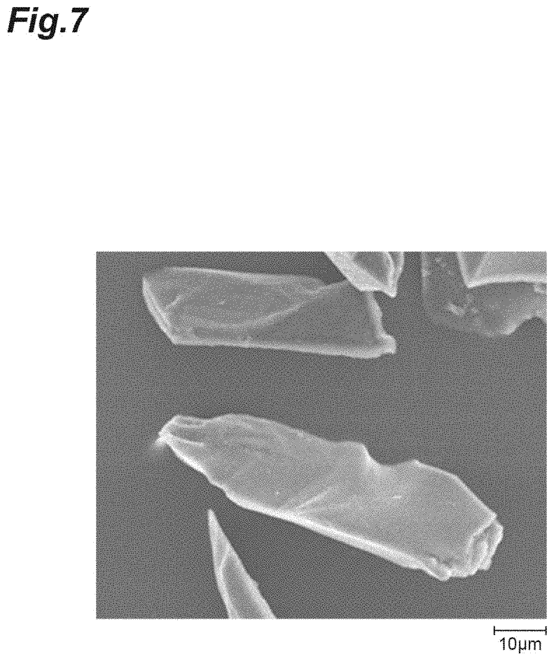

FIG. 7 is a scanning electron micrograph (magnification: 1,000 times) showing the obtained boron carbide powder.

A boron nitride crucible was filled with the prepared boron carbide powder. Thereafter, a resistance heating furnace was used to heat the boron carbide powder for 10 hours under the conditions of 2,000° C. and 0.85 MPa in a nitrogen gas atmosphere. In this manner, a fired product containing boron carbonitride (B₄CN₄) was obtained.

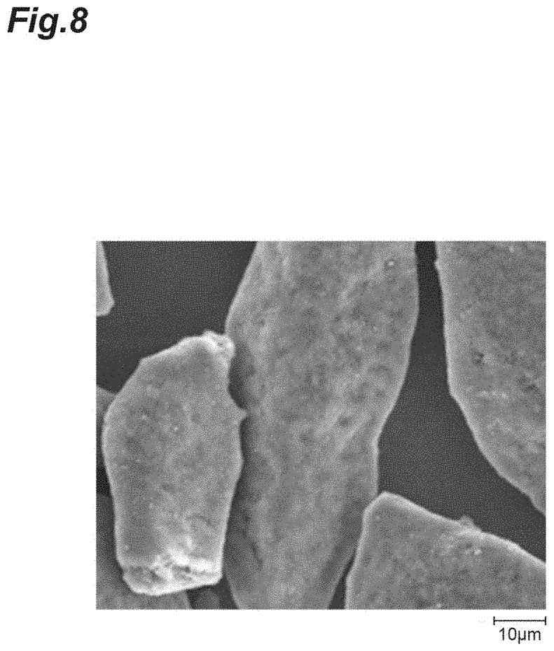

FIG. 8 is a scanning electron micrograph (magnification: 1,000 times) of a fired product. As shown in FIG. 8, it was confirmed that the fired product had a shape derived from the shape of the boron carbide powder.

The fired product was formulated with boric acid at a proportion so that the content of boric acid became 100 parts by mass based on 100 parts by mass of boron carbonitride, and the mixture was mixed with a henschel mixer. A boron nitride crucible was filled with the obtained mixture, and the temperature was raised from room temperature to 1,000° C. at a rate of temperature increase of 10° C./min in a nitrogen gas atmosphere under a pressure condition of 0.2 MPa using a resistance heating furnace. Subsequently, the temperature was raised from 1,000° C. to 2,000° C. at a rate of temperature increase of 2° C./min. By heating the mixture at 2,000° C. and holding it for 6 hours, a boron nitride containing agglomerated particles obtained by aggregating primary particles was obtained.

FIG. 3 is a scanning electron micrograph (magnification: 1,000 times) of the boron nitride powder obtained in Example 1. As shown in FIG. 3, it was confirmed that the boron nitride powder had a shape derived from the shape of the boron carbide powder.

The obtained agglomerated boron nitride was disintegrated with a henschel mixer. Thereafter, the disintegrated powder was classified with a nylon sieve having a sieve opening of 90 μm to obtain a boron nitride powder.

<Evaluation of Powder>

The orientation index [I(002)/I(100)] of the boron nitride powder was obtained using an X-ray diffractometer (manufactured by Rigaku Corporation, trade name: ULTIMA-IV) according to the following procedure. A 0.2-mm deep concave portion of a glass cell attached to the X-ray diffractometer was filled with the boron nitride powder. The sample with which the concave portion was filled was solidified at a set pressure M using a molding machine (manufactured by AmenaTec Limited, trade name: PX700) for a powder sample to produce a measurement sample.

In a case where the surface of the filler solidified with the molding machine was not smooth, the surface thereof was manually smoothed and used as a measurement sample. The measurement sample was irradiated with X-rays, and the peak intensity ratio of the plane (002) to the plane (100) of boron nitride after base line correction was performed was calculated and regarded as an orientation index [I(002)/I(100)]. The results are as shown in Table 1.

The average particle diameter of the boron nitride powder was measured with a particle size distribution measuring device (device name: LS-13 320) for a laser diffraction scattering method manufactured by Beckman Coulter Inc. according to ISO 13320:2009. The measurement was performed without subjecting the boron nitride powder to a homogenizer. The average particle diameter is a cumulative 50% particle diameter (median diameter, d50) of cumulative particle size distribution. When measuring the particle size distribution, water was used as a solvent for dispersing the aggregate and hexametaphosphoric acid was used as a dispersing agent. At this time, a numerical value of 1.33 was used for the refractive index of water and a numerical value of 1.80 was used for the refractive index of the boron nitride powder. The particle diameter of the boron carbide powder was also measured through the same method. The measurement results are as shown in Table 1.

The aspect ratios of the boron nitride powder and the boron carbide powder were obtained according to the following procedure. First, the boron nitride powder was observed with a scanning electron microscope (magnification: 200 to 2,000 times). As shown in FIG. 3, two points on the outer edge on the surface of the agglomerated particle with the largest spacing were selected. A line segment connecting these two points was the long side L1. In addition, another two points on the outer edge of the agglomerated particle 10 with the largest spacing in a direction orthogonal to this long side L1 were selected. A line segment connecting these two points was the short side L2. The lengths (La and Lb) of the long side L1 and the short side L2 drawn in this manner were obtained.

Arbitrary 100 agglomerated particles were selected in the scanning electron microscope image as shown in FIG. 3 and La/Lb values of the respective agglomerated particles were calculated to obtain an arithmetic average value of the La/Lb values. The obtained arithmetic average value is as shown in the “Aspect ratio” column of Table 1.

The aspect ratio of the boron carbide powder was also obtained through the same method as that for the boron nitride powder. The results are as shown in Table 1.

### Example 2

A boron carbide powder was obtained in the same manner as in Example 1 except that the pulverization time with the ball mill during preparation of the boron carbide powder was 40 minutes, the pulverized powder was classified with a vibration sieve having an opening of 38 μm, and the boron carbide powder obtained had particle diameters of larger than or equal to 18 μm due to airflow classification of the Classiel classifier. Then, the powder was evaluated in the same manner as in Example 1. The results are as shown in Table 1.

### Example 3

A boron carbide powder was obtained in the same manner as in Example 1 except that the pulverization time with the ball mill during preparation of the boron carbide powder was 50 minutes, the pulverized powder was classified with a vibration sieve having an opening of 45 μm, and the boron carbide powder obtained had particle diameters of larger than or equal to 15 μm due to airflow classification of the Classiel classifier. Then, the powder was evaluated in the same manner as in Example 1. The results are as shown in Table 1.

### Example 4

A boron carbide powder was obtained in the same manner as in Example 1 except that the pulverization time with the ball mill during preparation of the boron carbide powder was 70 minutes, the pulverized powder was classified with a vibration sieve having an opening of 53 μm, and the boron carbide powder obtained had particle diameters of larger than or equal to 8 μm due to airflow classification of the Classiel classifier. Then, the powder was evaluated in the same manner as in Example 1. The results are as shown in Table 1.

### Example 5

A boron carbide powder was obtained in the same manner as in Example 1 except that the pulverization time with the ball mill during preparation of the boron carbide powder was 120 minutes, the pulverized powder was classified with a vibration sieve having an opening of 25 μm, and the boron carbide powder obtained had particle diameters of larger than or equal to 5 μm due to airflow classification of the Classiel classifier. Then, the powder was evaluated in the same manner as in Example 1. The results are as shown in Table 1.

### Example 6

A boron carbide powder was obtained in the same manner as in Example 1 except that the pulverization time with the ball mill during preparation of the boron carbide powder was 30 minutes, the pulverized powder was classified with a vibration sieve having an opening of 63 μm, and the boron carbide powder obtained had particle diameters of larger than or equal to 25 μm due to airflow classification of the Classiel classifier. Then, the powder was evaluated in the same manner as in Example 1. The results are as shown in Table 1.

### Example 7

A boron carbide powder was obtained in the same manner as in Example 1 except that the pulverization time with the ball mill during preparation of the boron carbide powder was 25 minutes, the pulverized powder was classified with a vibration sieve having an opening of 75 μm, and the boron carbide powder obtained had particle diameters of larger than or equal to 35 μm due to airflow classification of the Classiel classifier. Then, the powder was evaluated in the same manner as in Example 1. The results are as shown in Table 1.

### Comparative Example 1

A boron carbide powder was obtained in the same manner as in Example 1 except that the rotation frequency and the pulverization time of the ball mill during preparation of the boron carbide powder were respectively 80 rpm and 90 minutes, the pulverized powder was classified with a vibration sieve having an opening of 75 μm, and the classification with the Classiel classifier was not performed. Then, the powder was evaluated in the same manner as in Example 1. The results are as shown in Table 1.

### Comparative Example 2

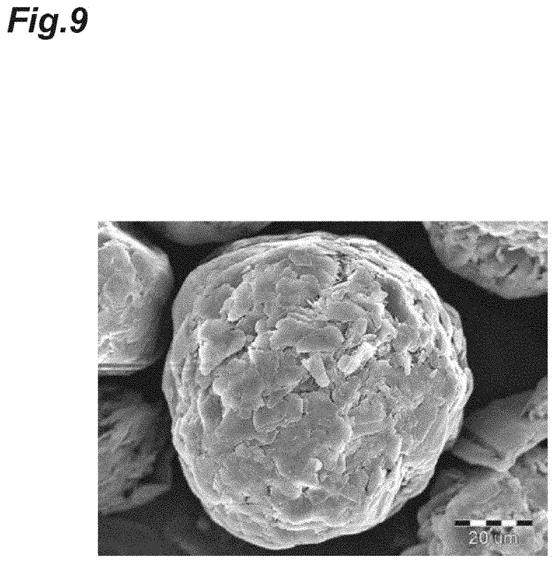

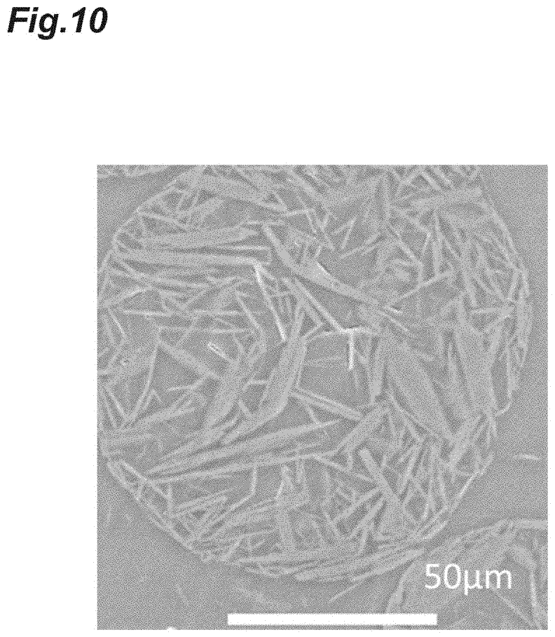

A boron nitride powder in which spherical particles as shown in FIGS. 9 and 10 were aggregated was prepared through a granulation step according to a commercially available spray-drying method. This boron nitride powder was evaluated in the same manner as in Example 1. The results are as shown in Table 1.

None of the comparative examples were boron nitride powders in which in-plane directions of primary particles were oriented in a direction parallel to a short-side direction of an agglomerated particle. In contrast, in-plane directions of primary particles constituting the agglomerated particle contained in each boron nitride powder of Examples 1 to 7 were oriented in a direction parallel to a short-side direction of the agglomerated particle as shown in FIG. 1.

TABLE 1

| | Boron carbide | | | | |
|---|---|---|---|---|---|
| | powder | | Boron nitride powder | | |
| | Average | | | Average | |
| | particle | | | particle | |
| | diameter | Aspect | Orientation | diameter | Aspect |
| | [μm] | ratio | index | [μm] | ratio |
| Example 1 | 30 | 2.5 | 5.5 | 50 | 2.0 |
| Example 2 | 30 | 8.0 | 3.8 | 50 | 6.0 |
| Example 3 | 30 | 4.4 | 4.5 | 50 | 3.8 |
| Example 4 | 30 | 1.8 | 6.3 | 50 | 1.4 |
| Example 5 | 10 | 3.9 | 4.5 | 18 | 3.4 |
| Example 6 | 50 | 4.0 | 4.5 | 70 | 3.5 |
| Example 7 | 60 | 4.0 | 4.5 | 90 | 3.5 |
| Comparative | 30 | 1.3 | 7.0 | 50 | 1.1 |
| Example 1 | | | | | |
| Comparative | — | — | 8.0 | 50 | 1.0 |
| Example 2 | | | | | |

<Production of Heat Dissipation Sheet (Composite Material)>

The characteristics of the obtained boron nitride powders as a filler for a resin were evaluated. A mixture of 100 parts by mass of a naphthalene-type epoxy resin (manufactured by DIC CORPORATION, trade name of HP4032) and 10 parts by mass of imidazoles (manufactured by Shikoku Chemicals Corporation, trade name of 2E4MZ-CN) as a curing agent was prepared. 50 parts by volume of each boron nitride powder was mixed with 100 parts by volume of the mixture. A PET sheet was coated with the mixture so as to have a thickness of 0.3 mm, and defoaming under reduced pressure at 500 Pa was performed for 10 minutes. Thereafter, uniaxial pressing was performed for 60 minutes under the condition of a pressure of 160 kg/cm² while heating the coating at 150° C. to obtain a heat dissipation sheet (composite material) having a thickness of 0.5 mm.

<Evaluation of Heat Dissipation Sheet>

The thermal conductivity (H: unit of W/(m·K)) of the heat dissipation sheet in the uniaxial pressing direction was calculated by H=A×B×C using thermal diffusivity (A: unit of m²/sec), density (B: unit of kg/m³), and specific heat capacity (C: unit of J/(kg·K)). The thermal diffusivity was measured through a laser flash method using a sample obtained by processing the sheet so as to have a size of length×width×thickness=10 mm×10 mm×0.3 mm. Xenon Flash Analyzer (manufactured by NETZSCH, trade name: LFA447 NanoFlash) was used as a measurement device. The density was measured through an Archimedes method. The specific heat capacity was measured using a differential scanning calorimeter (manufactured by Rigaku Corporation, device name: ThermoPlusEvo DSC8230). The measurement results are as shown in Table 2. The thermal conductivity (W/(m·K)) was described as a relative value, and it was 1.0 in Comparative Example 1.

The orientation index [I(002)/I(100)] of the heat dissipation sheet was obtained using an X-ray diffractometer (manufactured by Rigaku Corporation, trade name: ULTIMA-IV) according to the same procedure as that for the boron nitride powder. The heat dissipation sheet was used as a measurement sample and set in a sample holder of an X-ray diffractometer for analysis. The measurement sample was irradiated with X-rays, and the peak intensity ratio of the plane (002) to the plane (100) of boron nitride after base line correction was performed was calculated and regarded as an orientation index [I(002)/I(100)]. The results are as shown in Table 2.

TABLE 2

| | Heat dissipation sheet (composite material) | |
|---|---|---|
| | Thermal conductivity | Orientation |
| | as relative value | index |
| Example 1 | 1.4 | 5.0 |
| Example 2 | 1.5 | 3.3 |
| Example 3 | 1.5 | 4.0 |
| Example 4 | 1.3 | 5.4 |
| Example 5 | 1.3 | 4.0 |
| Example 6 | 1.5 | 4.5 |
| Example 7 | 1.6 | 4.2 |
| Comparative Example 1 | 1.0 | 6.9 |
| Comparative Example 2 | 0.7 | 20 |

### REFERENCE SIGNS LIST

10: Agglomerated particle, 11: Primary particles, 20: Composite material, 22: Resin, 50: Boron nitride powder.

1. A boron nitride powder comprising:
an agglomerated particle obtained by aggregating flaky primary particles,
wherein in-plane directions of the primary particles are oriented in a direction parallel to a short-side direction of the agglomerated particle.

2. The boron nitride powder according to claim 1,
wherein an orientation index [I(002)/I(100)] is less than or equal to 6.5.

3. A boron nitride powder comprising:
an agglomerated particle obtained by aggregating flaky primary particles,
wherein an orientation index [I(002)/I(100)] is less than or equal to 6.5.

4. The boron nitride powder according to claim 2,
wherein the orientation index is greater than or equal to 2.0 and less than 6.0.

5. The boron nitride powder according to claim 1,
wherein an average particle diameter is 15 to 200 μm.

6. The boron nitride powder according to claim 1,
wherein an aspect ratio is 1.3 to 9.0.

7. A method for producing a boron nitride powder, comprising:
a nitriding step of firing a boron carbide powder having an aspect ratio of 1.5 to 10 in a nitrogen pressurized atmosphere to obtain a fired product; and
a crystallization step of heating a formulation that contains the fired product and a boron source to produce flaky boron nitride primary particles and obtaining the boron nitride powder containing an agglomerated particle obtained by aggregating the primary particles.

8. The method for producing the boron nitride powder according to claim 7,
wherein in the crystallization step, the boron nitride powder in which in-plane directions of the primary particles are oriented in a direction parallel to a short-side direction of the agglomerated particle is obtained.

9. The method for producing the boron nitride powder according to claim 7,
wherein in the crystallization step, the boron nitride powder having an orientation index [I(002)/I(100)] of less than or equal to 6.5 is obtained.

10. A composite material comprising:
a boron nitride powder containing an agglomerated particle obtained by aggregating flaky primary particles; and
a resin,
wherein an orientation index [I(002)/I(100)] of the composite material is less than or equal to 6.0.

11. A composite material comprising:
the boron nitride powder according to claim 1; and
a resin.

12. A heat dissipation member having the composite material according to claim 10.

13. The boron nitride powder according to claim 3,
wherein the orientation index is greater than or equal to 2.0 and less than 6.0.

14. The boron nitride powder according to claim 3,
wherein an average particle diameter is 15 to 200 μm.

15. The boron nitride powder according to claim 3,
wherein an aspect ratio is 1.3 to 9.0.

16. A composite material comprising:
the boron nitride powder according to claim 3 and a resin.
